(19) United States
(12) Patent Application Publication
(10) Pub. No.: US 2026/0150296 A1
(43) Pub. Date: May 28, 2026

(54) SELECTOR FOR VERTICAL PLANAR CELL AND IN-PILLAR CELL STRUCTURES

(71) Applicant: Micron Technology, Inc., Boise, ID (US)

(72) Inventors: Jun Fujiki, Boise, ID (US); Yoshiaki Fukuzumi, Yokohama (JP)

(21) Appl. No.: 19/379,517

(22) Filed: Nov. 4, 2025

Related U.S. Application Data
(60) Provisional application No. 63/725,379, filed on Nov. 26, 2024.

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

Methods, systems, and devices for selector for vertical planar cell and in-pillar cell structures are described. Memory cell channels may be independently selectable when coupled with a common bit line contact. The memory cell channels may be formed in a stack of materials and within a memory slot or a memory pillar. The memory cell channels may be independently selectable based one or more implantation regions, a staircase formation, or both.

### CROSS REFERENCE

The present Application for Patent claims priority to U.S. patent application Ser. No. 63/725,379 by Fujiki et al., entitled “SELECTOR FOR VERTICAL PLANAR CELL AND IN-PILLAR CELL STRUCTURES,” filed Nov. 26, 2024, which is assigned to the assignee hereof, and which is expressly incorporated by reference in its entirety herein.

### TECHNICAL FIELD

The following relates to one or more systems for memory, including an apparatus including a selector for vertical planar cell and in-pillar cell structures.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory system that supports formation of an apparatus including a selector for vertical planar cell and in-pillar cell structures in accordance with examples as disclosed herein.

FIGS. 2A through 2M shows an example of a memory architecture that supports formation of an apparatus including a selector for vertical planar cell and in-pillar cell structures in accordance with examples as disclosed herein.

FIGS. 3A and 3B show examples of a memory architecture that supports formation of an apparatus including a selector for vertical planar cell and in-pillar cell structures in accordance with examples as disclosed herein.

FIGS. 4A through 4D show examples of a memory architecture that supports formation of an apparatus including a selector for vertical planar cell and in-pillar cell structures in accordance with examples as disclosed herein.

FIGS. 5A and 5B show examples of a memory architecture that supports formation of an apparatus including a selector for vertical planar cell and in-pillar cell structures in accordance with examples as disclosed herein.

FIGS. 6A and 6B show examples of a memory architecture that supports formation of an apparatus including a selector for vertical planar cell and in-pillar cell structures in accordance with examples as disclosed herein.

FIGS. 7A through 7C show examples of a memory architecture that supports formation of an apparatus including a selector for vertical planar cell and in-pillar cell structures in accordance with examples as disclosed herein.

FIG. 8 shows a block diagram of a manufacturing system that supports formation of an apparatus including a selector for vertical planar cell and in-pillar cell structures in accordance with examples as disclosed herein.

FIG. 9 shows a flowchart illustrating a method or methods that support formation of an apparatus including a selector for vertical planar cell and in-pillar cell structures in accordance with examples as disclosed herein.

### DETAILED DESCRIPTION

Some memory systems (e.g., apparatuses) include vertical planar memory cells or in-pillar memory cells, where the memory cell transistors may be connected within a stack of materials formed on a substrate (e.g., a 3D not-and (NAND) memory configuration). In some examples, such memory cell configurations may increase a density of memory cells deposited within the stack of materials, where memory cells may be accessed via one or more memory cell channels extending through the stack. The memory cell channels may be formed relatively close to one another, thereby further increasing memory cell density and improving capabilities of a memory system including the stack of materials. However, forming memory cell channels that are close in proximity may result in the memory system being unable to individually select memory cell channels. For example, a contact coupling a memory cell channel with a bit line (e.g., activated by the memory system to select a memory cell channel for access) may be relatively large in comparison to the size of the memory cell channel observed from a top of the stack of materials. As such, a bit line contact may couple with multiple memory cell channels, and activating the bit line may result in activation of the multiple memory cell channels.

Techniques, systems, apparatuses, and devices described herein provide for selection of individual memory cell channels when multiple memory cell channels are coupled with the same bit line contact. In some examples, a stack of materials may be implanted with a first material (e.g., phosphorus or boron) in one or more different regions of the stack of materials, such that each memory cell channel in a group of memory cell channels coupled with the same bit line contact may be coupled with or otherwise include materials having a different level of implantation. The first material may be configured to change electrical properties of memory cell channels that overlap with each region (e.g., changing a threshold voltage profile across of a group of memory cell channels coupled with the same contact). In such examples, a bit line contact coupled with multiple memory cell channels may be used to select an individual memory cell channel at a given time by applying different levels of exposure to the material of each memory cell channel and subsequently biasing the memory cell channels. In some cases, the stack may be formed in a staircase formation, such that each memory cell channel (or pair of memory cell channels) is coupled with a different word line at a different level or tier in the stack. The stack may further be implanted with a material configured to change electrical properties of at least some of the memory cells so that memory cell channels coupled with a same staircase tier may still be independently selectable.

The formation of the memory cell channels described herein may be supported by expanding a dummy pillar cavity for accessing a slit including the memory cell channels. The memory cell channels may be formed via removal of material and deposition of material through the dummy pillar cavity. Multiple removal phases may be performed in which recesses are iteratively formed in the slit and marked with oxidized notches, and the memory cell channels may be subsequently formed within respective recesses. As described herein, removal of material may be performed using one or more removal techniques, including etching material, exhuming the material, stripping the material, other removal techniques, or the like, such that at least a portion of the removed material is no longer present after performance of a removal operation. Such techniques may improve reliability of forming the memory cell channel structure with reduced interference and improved density.

In addition to applicability in memory systems as described herein, techniques for selectors for vertical pillar cell and in-pillar cell structures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory cell density, which may improve user experience, among other benefits.

Features of the disclosure are illustrated and described in the context of systems, devices, and circuits. Features of the disclosure are further illustrated and described in the context of memory architectures and flowcharts.

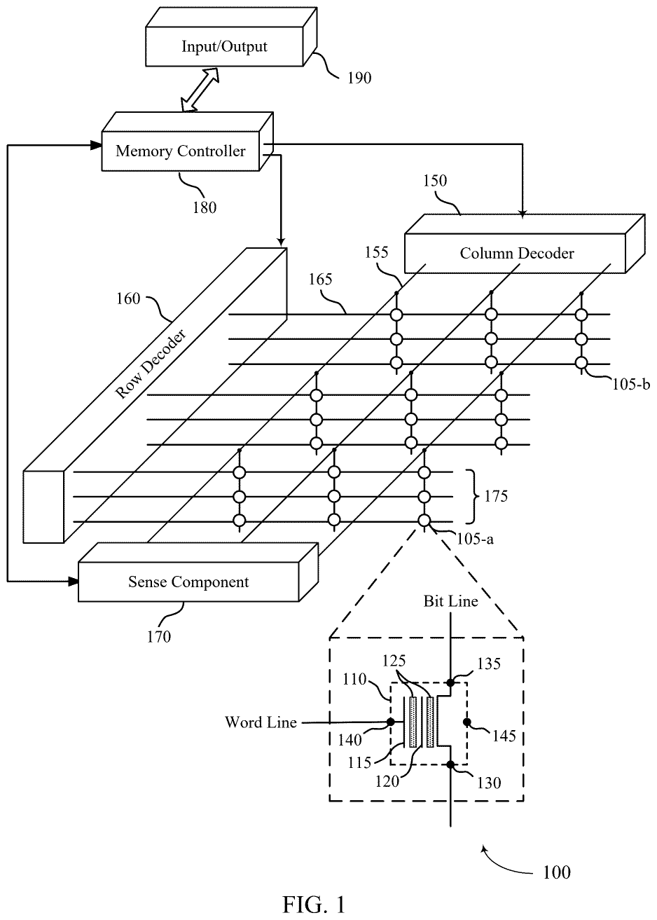

FIG. 1 shows an example of a memory system 100 that supports selector for vertical planar cell and in-pillar cell structures in accordance with examples as disclosed herein. FIG. 1 is an illustrative representation of various components and features of the memory system 100. As such, the components and features of the memory system 100 are shown to illustrate functional interrelationships, and not necessarily physical positions within the memory system 100. Further, although some elements included in FIG. 1 are labeled with a numeric indicator, some other corresponding elements are not labeled, even though they are the same or would be understood to be similar, in an effort to increase visibility and clarity of the depicted features.

The memory system 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

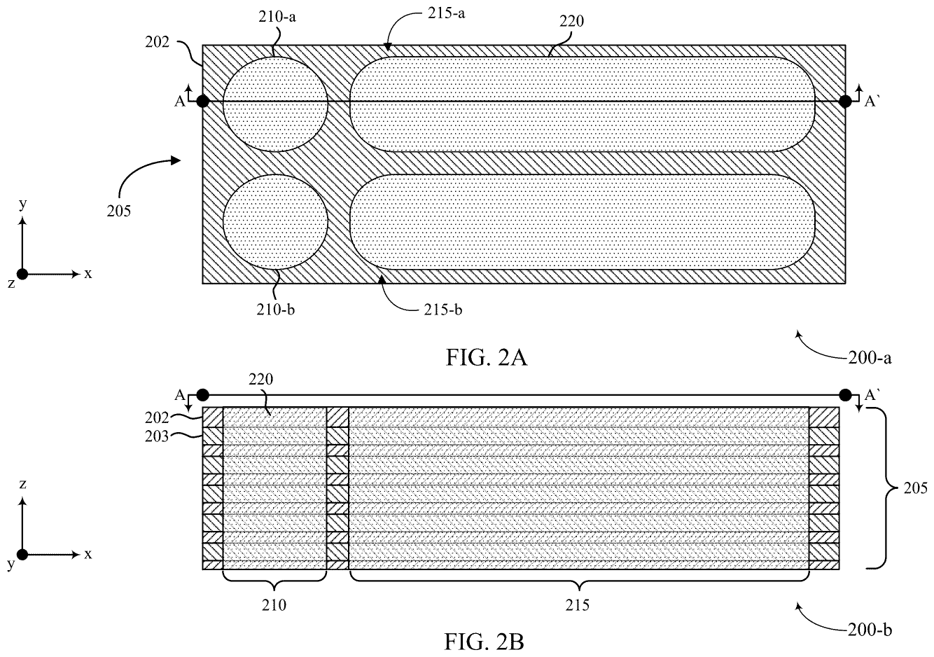

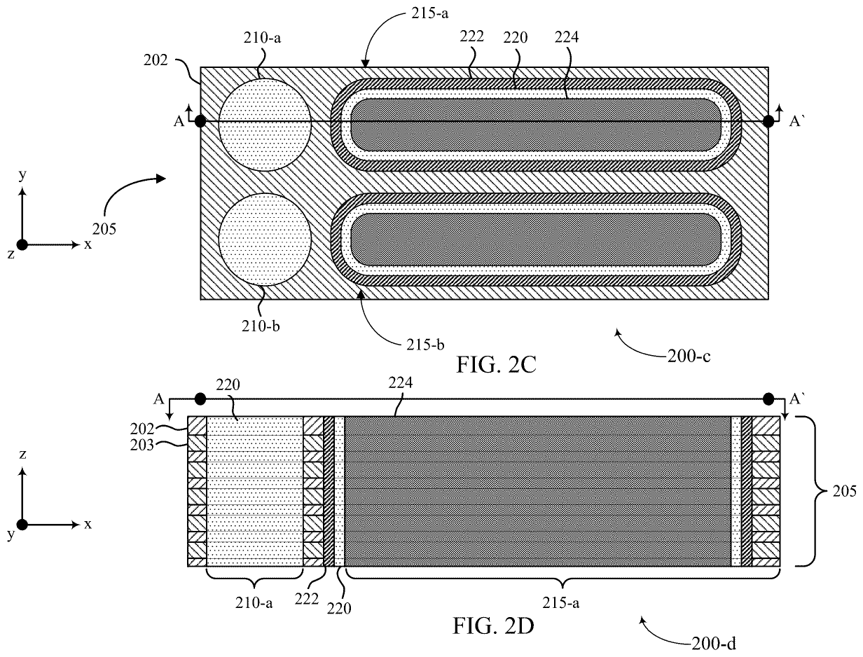

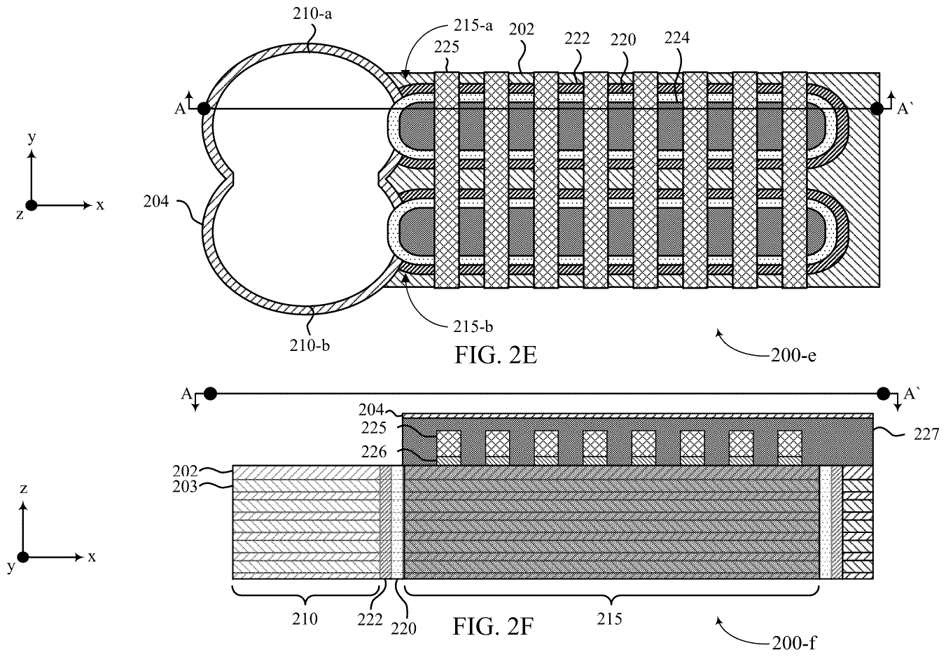

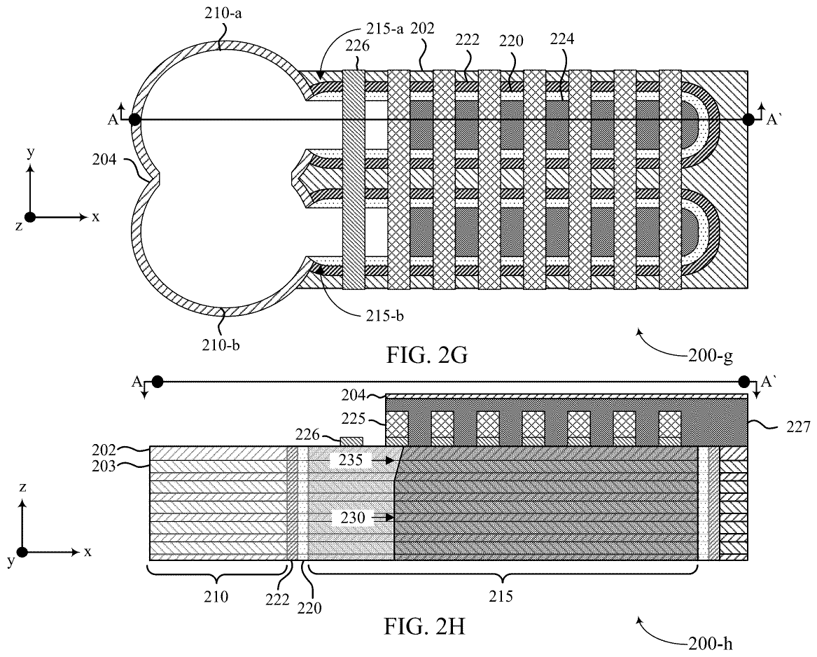

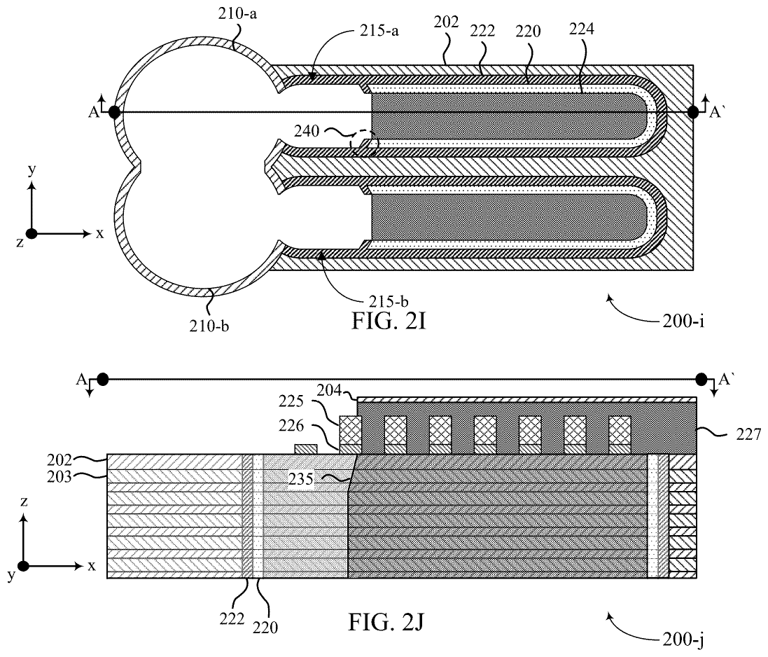

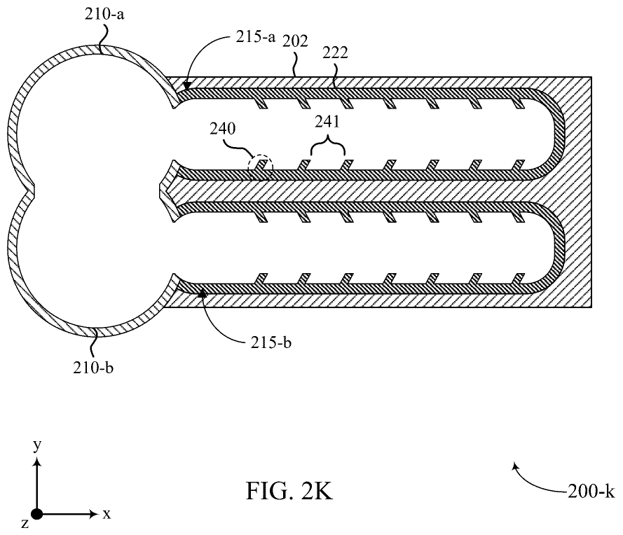

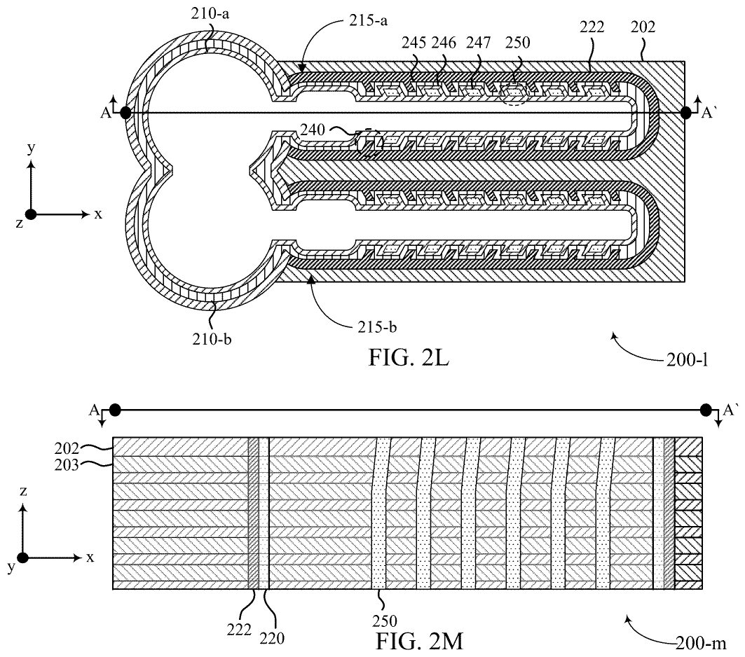

In some cases, a memory system 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory system 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory system 100.

Some memory systems 100 (e.g., apparatuses) include vertical planar memory cells 105 or in-pillar memory cells 105, where the memory cell transistors may be connected within a stack of materials formed on a substrate (e.g., a 3D NAND memory configuration). In some examples, such memory cell configurations may increase a density of memory cells 105 deposited within the stack of materials, where memory cells 105 may be accessed via one or more memory cell channels extending through the stack. The memory cell channels may be formed relatively close to one another, thereby further increasing memory cell density and improving capabilities of a memory system 100 including the stack of materials. However, forming memory cell channels that are close in proximity may result in the memory system being unable to individually select memory cell channels. For example, a contact coupling a memory cell channel with a bit line 155 (e.g., activated by the memory system 100 to select a memory cell channel for access) may be relatively large in comparison to the size of the memory cell channel observed from a top of the stack of materials. As such, a bit line contact may couple with multiple memory cell channels, and activating the bit line may result in activation of the multiple memory cell channels.

Techniques, systems, apparatuses, and devices described herein provide for selection of individual memory cell channels when multiple memory cell channels are coupled with the same bit line contact. In some examples, a stack of materials may be implanted with a first material (e.g., phosphorus or boron) in one or more different regions of the stack of materials, such that each memory cell channel in a group of memory cell channels coupled with the same bit line contact may be coupled with or otherwise include materials having a different level of implantation. The first material may be configured to change electrical properties of memory cell channels that overlap with each region (e.g., changing a threshold voltage profile across of a group of memory cell channels coupled with the same contact). In such examples, a bit line contact coupled with multiple memory cell channels may be used to select an individual memory cell channel at a given time by applying different levels of exposure to the material of each memory cell channel and subsequently biasing the memory cell channels. In some cases, the stack may be formed in a staircase formation, such that each memory cell channel (or pair of memory cell channels) is coupled with a different word line 165 at a different level or tier in the stack. The stack may further be implanted with a material configured to change electrical properties of at least some of the memory cells so that memory cell channels coupled with a same staircase tier may still be independently selectable.

The formation of the memory cell channels described herein may be supported by expanding a dummy pillar cavity for accessing a slit including the memory cell channels. The memory cell channels may be formed via removal and deposition through the dummy pillar cavity. Multiple removal phases may be performed in which recesses are iteratively formed in the slit and marked with oxidized notches, and the memory cell channels may be subsequently formed within respective recesses. As described herein, removal of material may be performed via etching, stripping, exhuming, or the like, such that at least a portion of the removed material is no longer present after performance of a removal operation. Such techniques may improve reliability of forming the memory cell channel structure with reduced interference and improved density.

FIGS. 2A through 2M show examples of memory architectures 200 after various processing steps that support a selector for vertical planar cells and in-pillar cells as described herein. The memory architectures 200 may be an example of a portion of an apparatus, such as a memory system 100 described with reference to FIG. 1. FIGS. 2A through 2M show various views and steps of forming a memory architecture 200. For example, the memory architectures 200 may illustrate operations associated with forming an apparatus including memory cell channels extending into a stack of materials. In some cases, the memory architectures 200 may support memory cell channels connected to the same bit line contact being individually selectable based on implanting a first material (e.g., phosphorus or boron) in one or more regions of the stack of materials, such that the memory cell channels connected to the same bit line contact have different electrical properties.

For illustrative purposes, aspects of the memory architecture may be described with reference to an x-direction, a y-direction, and a z-direction of the illustrated coordinate systems. For example, memory architectures 200-a, 200-c, 200-e, 200-g, 200-h, 200-j, and 200-l illustrate the memory architecture from a top-down view, where a substrate of the memory architecture may be associated with an xy-plane, and where the memory architecture extends a distance along the z-direction. Additionally, the memory architectures 200-b, 200-d, 200-f, 200-h, 200-i, 200-k, and 200-m illustrate the memory architecture with a cross-sectional view, such that a portion of the memory architecture may be removed from the trimetric view to illustrate a cross-section of the memory architecture in the xz-plane, the xy-plane, or both. Although the memory architectures 200 illustrate examples of relative dimensions and quantities of various features, aspects of the memory architectures 200 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, removals (e.g., etches, exhumes, strips), other processing steps, or the like.

Processing steps illustrated in and described with reference to FIGS. 2A through 2M may be performed by a manufacturing system, such as a semiconductor fabrication system configured to perform additive operations such as deposition, formation, bonding, and/or coupling, subtractive operations such as removing, etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 2A illustrates an example of a memory architecture 200-a after one or more first processing steps associated with forming memory cell channels within memory slots formed in a stack of materials 205. The memory architecture 200-a illustrates bird's eye view (e.g., a top-down) view of a top layer of the stack of materials 205 in the xy-plane. The stack of materials 205 may be formed above a substrate and may include layers of one or more materials. For example, the memory architecture 200-a shows a top layer of the stack of materials 205, which may be made of or otherwise include a sacrificial material 202. The stack of materials 205 may include one or more additional layers of the sacrificial material 202 and one or more layers of an oxide material 203 positioned below the top layer relative to a substrate, as described in greater detail with reference to FIG. 2B.

In some cases, one or more pillars may be formed in the stack of materials 205 (e.g., the pillars may extend from the top layer of the stack of materials 205 towards the substrate in the z direction). The pillar 210-a and a pillar 210-b may be formed by etching one or more holes through at least a portion of the stack of materials 205 and depositing a polymer material 220 (e.g., a dummy material, a placeholder material) into respective holes in the stack of materials 205. For example, the one or more first processing steps may include etching respective first holes in the stack of materials (e.g., material may be removed from the stack of materials 205 to form a hole for the pillar 210-a) to form the pillars 210. In some cases, the pillars 210 may facilitate access to respective memory slots 215. For example, the pillar 210-a may provide access to a memory slot 215-a and the pillar 210-b may provide access to a memory slot 215-b. In some cases, the memory slots 215 may be formed from respective slits in the stack of materials 205. For example, the one or more first processing steps may include etching respective second cavities in the stack of materials to from the memory slots 215 that extend from the top layer of the stack of materials 205 through at least a portion of the stack of materials 205 or all the way to a substrate positioned beneath the stack of materials 205. The second cavities may be filled with the polymer material 220 after the cavities are formed. The memory slots 215 may be relatively longer than the pillars 210. For example, the pillars 210 may have a relatively circular shape, and the memory slots 215 may be elongated rectangular cavities with curved edges, for example (e.g., or an elongated ellipse with flat or straight sides, as another example).

FIG. 2B illustrates an example of a memory architecture 200-b after the one or more first processing steps associated with forming memory cell channels within memory slots formed in the stack of materials 205. For example, the memory architecture 200-b shows a cross-sectional view of the memory architecture 200-a in the xz-plane across the A-A′ line shown in FIG. 2A. As shown in the memory architecture 200-b, the stack of materials may include one or more layers of the sacrificial material 202 and one or more layers of the oxide material 203. In some cases, the layers of the sacrificial material 202 and the layers of the oxide material 203 may alternate in the vertical direction (z-direction) above a substrate. The memory architecture 200-b shows the pillar 210-a and the memory slot 215-a extending from the top layer of the stack of materials 205 to a substrate beneath the stack of materials 205 in the z-direction (e.g., vertically through the stack 205) and filled with the polymer material 220.

FIG. 2C illustrates an example of a memory architecture 200-c after one or more second processing steps associated with forming memory cell channels within the memory slots 215. The memory architecture 200-c illustrates a bird's eye view (e.g., a top-down) view of a top layer of the stack of materials 205 in the xy-plane after the one or more second processing steps are applied to the memory architecture 200-a. For example, the memory architecture 200-c may include the pillars 210-a and 210-b, as well as the memory slots 215-a and 215-b described with reference to FIG. 2A. The one or more second processing steps may include exhuming the memory slots 215 (e.g., removing the polymer material) and depositing one or more materials along a sidewall of the memory slots 215.

For example, a separation material 222 (e.g., a blocking oxide) may be deposited along the sidewall of the memory slots 215 (e.g., a sidewall of the cavity formed from exhuming the polymer material 220). The separation material 222 may form a liner that extends along the sidewalls of the memory slots 215 (e.g., all or a portion of the sidewall). After depositing the separation material 222, the polymer material 220 may be deposited (e.g., reintroduced to the memory slots 215) at the sidewall of the memory slots 215, which may result in the polymer material 220 lining the separation material 222. After depositing the polymer material 220, a sacrificial material 224 (e.g., a nitride material) may be deposited in the remaining cavity of the memory slots 215. The sacrificial material 224 may extend through the stack of materials 205 in the vertical direction (e.g., z-direction) and may be at least partially surrounded by the polymer material 220 and the separation material 222 in the xy plane.

FIG. 2D illustrates an example of a memory architecture 200-d after the one or more second processing steps associated with forming memory cell channels within the memory slots 215. For example, the memory architecture 200-d shows a cross-sectional view of the memory architecture 200-c in the xz plane across the A-A′ line shown in FIG. 2D. As shown in FIG. 2D, the sacrificial material 224 may extend from the top layer of the stack of materials 205 to the substrate positioned beneath the stack of materials 205. The separation material 222 and the polymer material 220 may similarly extend from the top layer of the stack of materials 205 to the substrate positioned beneath the stack of materials 205.

FIG. 2E illustrates an example of a memory architecture 200-e after one or more third processing steps associated with forming memory cell channels within the memory slots 215. For example, the memory architecture 200-e illustrates a bird's eye view (e.g., a top-down) view of a top layer of the stack of materials 205 in the xy-plane after the one or more third processing steps are performed on the memory architecture 200-c. In some examples, the one or more third processing steps may include depositing a high-k material 226 (e.g., an high-k material, illustrated in FIG. 2F) and a metal material 225 (e.g., an metal material) to form multiple strips that extend in the y-direction and are distributed across the memory slots 215 in a horizontal direction (e.g., the x-direction). The strips may be formed over the memory slots 215 and may not extend into the stack of materials 205. For example, the strips may be formed on top of the materials included in the memory slots 215 as described with reference to FIG. 2D.

The one or more third processing steps may further include expanding a size of the pillars 210 (e.g., by etching around the pillars 210) and removing the polymer material 220. Expanding the pillars 210 may provide for a manufacturer to access respective memory slots 215, such that the cavities of the pillars 210 contact the sacrificial material 224 and/or the polymer material 220 at the respective memory slots 215. In some cases, the one or more third processing steps may include depositing an oxide material 204 at a sidewall of the expanded pillars 210. The oxide material 204 may be at least partially surrounded by the sacrificial material 202 and the oxide material 203 in each layer of the stack of materials 205.

FIG. 2F illustrates an example of a memory architecture 200-f after the one or more third processing steps associated with forming memory cell channels within the memory slots 215. For example, the memory architecture 200-f shows a cross-sectional view of the memory architecture 200-e in the xz plane across the A-A′ line shown in FIG. 2E. As shown in FIG. 2F, the one or more strips may include a layer of the high-k material 226 below a layer of the metal material 225. In some examples, the one or more third processing steps may include depositing a thermoelectric (TE) material 227 above and between the strips of the high-k material 226 and the metal material 225 (e.g., a fill of the TE material 227). A chemical mechanical planarization (CMP) process may be performed to flatten a top of the TE material 227. Additionally, or alternatively, the oxide material 204 (e.g., a surface oxide) may be deposited above the TE material 227 (e.g., or a surface of the TE material 227 may be oxidized).

FIG. 2G illustrates an example of a memory architecture 200-g after one or more fourth processing steps associated with forming memory cell channels within the memory slots 215. For example, the memory architecture 200-g illustrates a bird's eye view (e.g., a top-down) view of a top layer of the stack of materials 205 in the xy-plane after the one or more fourth processing steps are performed on the memory architecture 200-e. The one or more fourth processing steps may include etching, via the pillars 210 based on the expansion of the pillars 210, a portion of the sacrificial material 224 from the memory slots 215. In the example illustrated by the memory architecture 200-g, the sacrificial material 224 may be etched to an axis, in the y-direction, that at least partially aligns with (e.g., is centered along, or otherwise extends along a portion of) a first strip of the metal material 225. The metal material 225 may be removed, exposing the high-k material 226. After the metal material 225 is removed, the sacrificial material 224 may be further removed (e.g., etched, stripped, exhumed) to a subsequent axis, in the y-direction, that at least partially overlaps with a second strip of the metal material 225.

FIG. 2H illustrates an example of a memory architecture 200-h after the one or more fourth processing steps associated with forming memory cell channels within the memory slots 215. For example, the memory architecture 200-h shows a cross-sectional view of the memory architecture 200-g in the xz plane across the A-A′ line shown in FIG. 2G. As shown in FIG. 2H, the metal material 225 may be removed from the first strip, exposing the high-k material 226, and the sacrificial material 224 may be etched to a center 230 of the subsequent strip. Additionally, the sacrificial material 224 may be recessed further in the x-direction at the top of the stack 205, such that the recess 235 is formed from the right end of the metal material 225 strip. Additionally, the oxide material 204 and the TE material 227 may be recessed (e.g., along with the sacrificial material 224) to the subsequent axis, in the y-direction, that at least partially overlaps with the second strip of the metal material 225.

FIG. 2I illustrates an example of a memory architecture 200-i after one or more fifth processing steps associated with forming memory cell channels within the memory slots 215. For example, the memory architecture 200-i illustrates a bird's eye view (e.g., a top-down) view of a top layer of the stack of materials 205 in the xy-plane after the one or more fifth processing steps are performed on the memory architecture 200-g. In some cases, the one or more fifth processing steps may include recessing the polymer material 220 from the memory slots 215 up to the strip of metal material 225 and high-k material 226 that the sacrificial material is etched to. Additionally, a portion of the polymer material 220 may be oxidized to form a notch 240 that tapers diagonally within the memory slots 215 such that the notch 240 is positioned above and aligns with the tapered recess 235 at the strip. In some cases, one notch 240 may be formed per sidewall of a memory slot 215 (e.g., two notches per memory slot 215), and may be aligned in pairs along axes, in the y-direction, at each sidewall.

FIG. 2J illustrates an example of a memory architecture 200-j after the one or more fifth processing steps associated with forming memory cell channels within the memory slots 215. For example, the memory architecture 200-j shows a cross-sectional view of the memory architecture 200-i in the xz plane across the A-A′ line shown in FIG. 2I. As shown in FIG. 2J, the oxidized notch may align with the tapered recess 235 of the oxidized polymer material 220, where the tapered recess 235 is formed from the center of a strip of the metal material 225 and the high-k material 226 to the right side of the strip (in the x-direction).

FIG. 2K illustrates an example of a memory architecture 200-k after one or more sixth processing steps associated with forming memory cell channels within the memory slots 215. For example, the memory architecture 200-k may be an example of the one or more sixth processing steps being performed on the memory architecture 200-i. The one or more sixth processing steps may include performing multiple phases to form oxidized notches 240 at each strip of the metal material 225 and the high-k material 226. For example, during each phase, the polymer material 220 may be removed from the memory slots 215 up to a strip of the metal material 225 and the high-k material 226 and the polymer material 220 may be oxidized at respective tapered recesses 235 to form the oxidized notches 240. The oxidized notches 240 may be formed at both sidewalls of each memory slot 215, and recesses 241 may be formed in spaces between notches 240 at the sidewalls of the memory slots 215.

FIG. 2L illustrates an example of a memory architecture 200-l after one or more seventh processing steps associated with forming memory cell channels within the memory slots 215. For example, the memory architecture 200-l may be an example of the one or more seventh processing steps being performed on the memory architecture 200-k. The one or more seventh processing steps may include depositing a storage material 245 (e.g., a storage nitride) in the memory slots 215 to line the sidewalls and notches 240 of the memory slots 215. The one or more seventh processing steps may include depositing an oxide material 246 (e.g., a tunnel oxide) in the memory slots 215 to line the storage material 245 in the memory slots 215. The one or more seventh processing steps may include depositing a polymer material 247 in spaces between notches 240 forming a memory cell channel 250. In some cases, the polymer material 247 may be recessed and a metal material may be deposited in the memory cell channels 250 to form the memory cell channels 250. The separation material 222 may line the outside of the memory slots 215.

The storage material 245 may extend vertically through the stack (e.g., in the z-direction) along the memory cell channels 250. As such, the storage material 245 may be positioned between (e.g., sandwiched between) a respective memory cell channel 250 and the sacrificial material 202 at each layer of the multiple layers of the sacrificial material 202. The sacrificial material 202 may ultimately be replaced, via a replacement gate process, with a metal material that may correspond to one or more word lines. As such, the intersection between the memory cell channel 250 and the metal material at each layer may include the storage material 245 and may form a memory cell.

FIG. 2M illustrates an example of a memory architecture 200-m after the one or more seventh processing steps associated with forming memory cell channels within the memory slots 215. For example, the memory architecture 200-m shows a cross-sectional view of the memory architecture 200-l in the xz plane across the A-A′ line shown in FIG. 2L. As shown in FIG. 2M, the memory cell channels 250 may taper according to the tapered recesses 235 and may extend from the top of the stack 205 to the bottom of the stack 205. The stack 205 may include the oxide material 203 and the sacrificial material 202. The memory slots may include a portion of the separation material 222 and the polymer material 220.

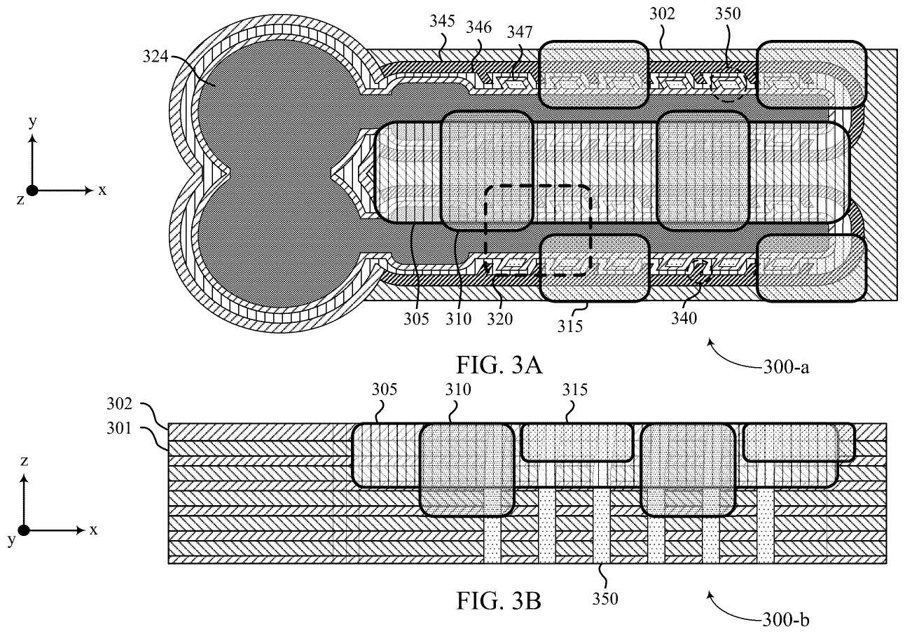

FIGS. 3A and 3B show examples of a memory architecture 300 that support selector for vertical planar cell and in-pillar cell structures in accordance with examples as disclosed herein. The memory architecture 300 may implement, or be implemented by, one or more aspects of the memory architecture 200. For example, the memory architecture 300 may be an example of the completed memory architecture 200 described and illustrated with reference to FIGS. 2L and 2M. The memory architecture 300 includes a stack of materials including an oxide material 302, a separation material 345, a storage material 346, and a polymer material 347 in memory cell channels 350, which may be examples of corresponding aspects described herein. The memory architecture 300 may include a stack of materials including alternating layers of the oxide material 302 and a sacrificial material 301. As described with reference to FIGS. 2A through 2M, the memory architecture 300 may be formed in an iterative process, such that the memory cell channels 350 are formed within recesses between two adjacent notches 340 of the separation material 345. In some examples, a sacrificial material 324 may be deposited to fill a remaining region within the stack (e.g., between rows of memory cell channels 350 in the y-direction.

FIG. 3A illustrates a memory architecture 300-a in the xy plane. The memory architecture 300-a shows an example of memory slots including memory cell channels 350 extending into a stack of materials. In some cases, the memory architecture 300-a may include one or more implantation regions of a first material (e.g., phosphorus or boron) configured to change electrical properties of memory cell channels 350. A first implantation region 305 may overlap with a first set of memory cell channels 350. A second implantation region 310 may overlap with a second set of memory cell channels 350. A third implantation region 315 may overlap with a third set of memory cell channels 350. The implantation regions may be discontinuous and placed at any point on the memory architecture 300-a, and are not limited to the example illustrated by the memory architecture 300-a. The implantation regions may change electrical properties of memory cell channels 350. For example, a channel group 320 may include memory cell channels 350 that each overlap with different implantation regions, which may result in each memory cell channel 350 having a different threshold access voltage. In some cases, the channel group 320 may couple with a common bit line contact. Thus, the voltage at the bit line contact may be applied to each memory cell channel 350 while enabling the memory cell channels 350 to be independently selected.

FIG. 3B illustrates a memory architecture 300-b in the xz plane (e.g., a cross sectional view of the memory architecture 300-a). As shown in FIG. 3B, the implantation regions 305, 310, and 315 may extend into the stack of materials at different depths. By implanting the first material at different depths for different implantation regions, the memory cell channels may be independently selectable when coupled with a common bit line contact. For example, the first material may be a conductive material (e.g., the phosphorus or boron), and a memory cell channel 350 overlapping the first material may have a lower threshold access voltage than a memory cell channel 350 not overlapping the first material. Additionally, an implantation region extending further into the stack than another implantation region (e.g., the implantation region 310 may extend deeper than the implantation region 305, which may extend deeper than the implantation region 315) may further lower the threshold access voltage. Thus, an access voltage suitable to activate a memory cell channel 350 overlapping the implantation region 310 may not result in activation of memory cell channels 350 overlapping the implantation region 305, the implantation region 315, or not overlapping with any implantation region. Further, applying a voltage to word lines (e.g., formed from the tiers of sacrificial material 301) at tiers of the stack beneath the implantation regions may adjust threshold access voltages such that memory cell channels 350 can be selected without activating memory cell channels 350 having a lower threshold access voltage. For example, ranges of word lines overlapping with implantation regions may adjust the threshold access profile over the range of word lines for the memory cell channel 350, allowing for selection of a certain memory cell channel 350 in the channel group 320.

As described in further detail with reference to FIGS. 2K through 2M, it is to be understood that each memory cell channel 350 may include or otherwise be coupled with one or more memory cells. A memory cell may, for example, be formed at an intersection between the memory cell channel 350 and a corresponding layer of a metal material. The sacrificial material 301 my subsequently be replaced, via a metallization operation, with a metal material. The layers between the oxide material 302 may thereby include conductive word lines. The storage material 346 described and illustrated in FIG. 3A may extend along each memory cell channel 350 in the vertical direction and between the memory cell channel 350 and the layers of the metal material. The storage material 346 sandwiched between a word line and the memory cell channel 350 may thereby store logic states for a corresponding memory cell as described herein. The memory cell channel 350 may represent an example of a drain-source or other conductive channel through the multiple memory cells within a cell pillar.

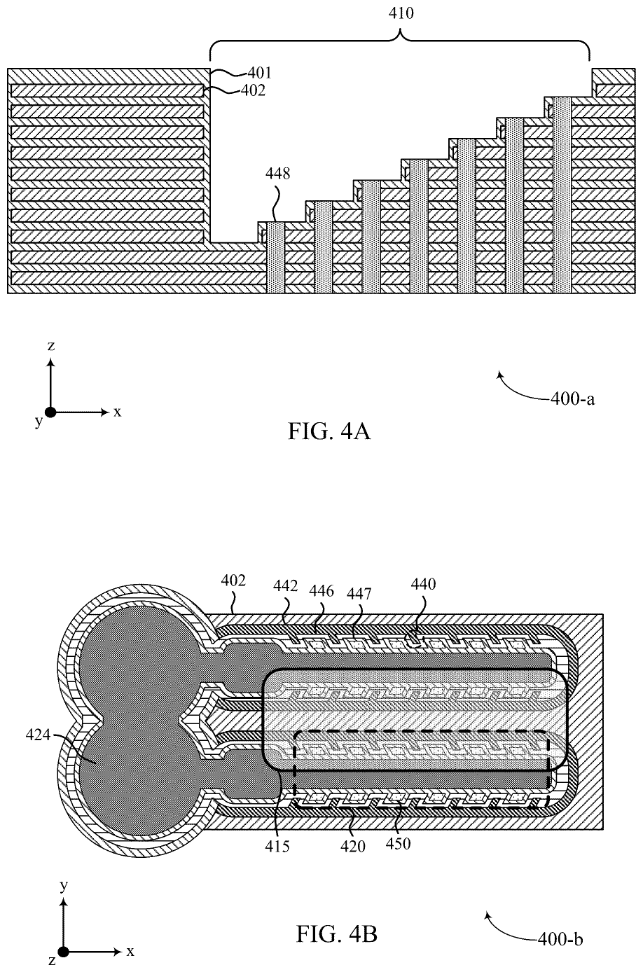

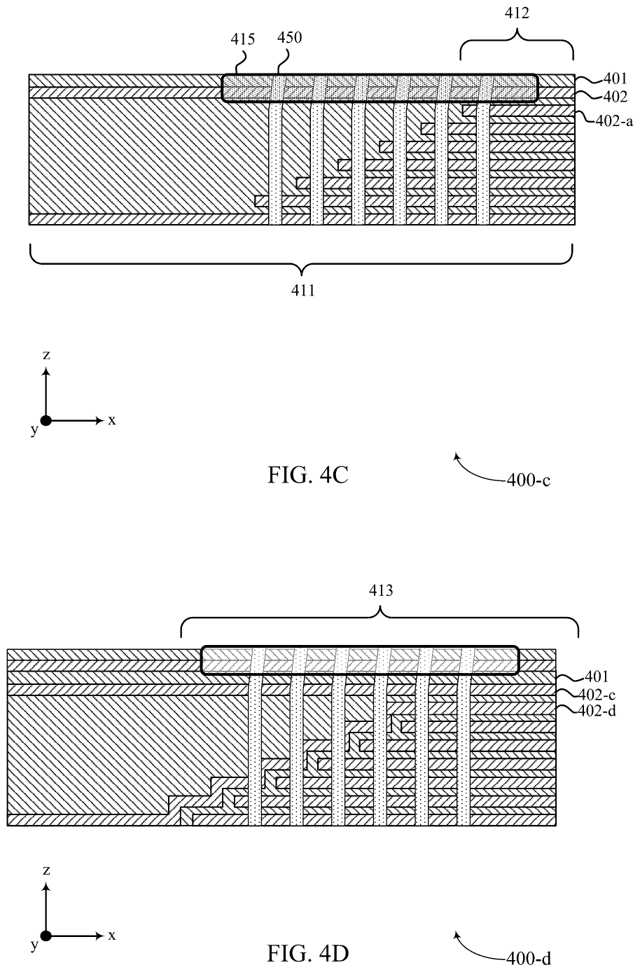

FIGS. 4A through 4D show examples of a memory architecture 400 that supports selector for vertical planar cell and in-pillar cell structures in accordance with examples as disclosed herein. The memory architecture 400 may implement one or more aspects of the memory architecture 200. For example, the memory architecture 400 may include a stack of materials including one or more layers of an oxide material 401 and a sacrificial material 402, where memory cell channels 450 may be formed in the stack of materials.

FIG. 4A illustrates an example of a memory architecture 400-a in the xz plane. For example, the memory architecture 400-a shows an example of a cross-sectional view of a stack of materials including holes 448 during the process of forming the stack including a cascading staircase formation. In accordance with the staircase formation, after alternating layers of the sacrificial material 402 and the oxide material 401 are formed, a portion of each layer of the sacrificial material 402 and the oxide material 401 may be recessed a respective length, starting with the first length 410 in a top level of the stack (e.g., a top-most pair of the oxide material 401 and the sacrificial material 402). The lengths by which each level is recessed may decrease as the etch extends vertically (e.g., in the z-direction) through the stack of materials, such that one or more of the bottom levels may not be recessed at all or may have a relatively small recessed portion.

The holes 448 may be formed within the stack in accordance with a process similar to the iterative formation process described with reference to FIGS. 2A through 2M. For example, one or more holes may be formed adjacent to the staircase and may be used to iteratively remove (e.g., etch back) portions of material and form memory cell channels that are separated by notches, as described with reference to FIG. 4B. Although the holes 448 are illustrated as extending to the same height as each tier of the stack in FIG. 4A, it is to be understood that each hole 448 may extend a same height, in some examples.

FIG. 4B illustrates an example of a memory architecture 400-b in the xy plane. For example, the memory architecture 400-b may show the memory architecture 400-a in a top-down view after one or more additional processing steps. For example, the memory architecture 400-b illustrates the architecture 400-a after the iterative removal and formation processes are performed to form the notches 440 of the separation material 442 that extend between adjacent memory cell channels 450. As part of the additional processing steps, the holes 448 illustrated in FIG. 4A may be filled with a metal material to form the memory cell channels 450, such that the memory cell channels 450 may couple with one or more memory cells (e.g., via storage material 446) to support accessing the one or more memory cells. The formation of the separation material 442, the notches 440, the storage material 446, the polymer material 447, the memory cell channels 450, and the sacrificial material 424 may be described in further detail elsewhere herein, including with reference to FIGS. 2A through 2M, and may be applied to the memory architecture 400-a including the staircase formation.

In some cases, the memory architecture 400-b may include an implantation region 415 of a first material (e.g., phosphorus or boron) configured to change electrical properties of memory cell channels 450 overlapping the implantation region 415. For example, based on the implantation region 415 and the staircase formation of the stack of materials, memory cell channels 450 within a channel group 420 may be independently selectable. For example, the memory cell channels 450 of the channel group 420 may couple with a common bit line contact, and may receive the same voltage when the bit line contact is activated. In some cases, a tier of the sacrificial material 402 (once replaced with a metal material to form word lines) may couple with two memory cell channel 450, one overlapping the implantation region 415 and one not. By activating the bit line contact and the word line, one of the two memory cell channels 450 coupled with the word line may activate due to the implantation region 415 changing the electrical properties of the memory cell channels 450 (e.g., lowering a threshold access voltage relative to non-overlapping memory cell channels 450). That is, the staircase formation alone may be insufficient to independently select between pairs of memory cell channels 450, and selection between the pairs of memory cell channels 450 may be achieved leveraging the staircase formation in addition to the implantation region 415. The memory architecture 400 includes a stack of materials including an oxide material 401, a separation material 442, a storage material 446, and a polymer material 447 in memory cell channels 450, which may be examples of corresponding aspects described herein.

FIG. 4C illustrates an example of a memory architecture 400-c in the xz plane. The memory architecture 400-c may be a cross-sectional view of the memory architecture 400-b. As shown in FIG. 4C, the implantation region 415 may extend a length into the stack of materials, and memory cell channels 450 may couple with respective tiers of the sacrificial material 402 in the staircase formation. By overlapping the implantation region 415 with memory cell channels 450 and forming the sacrificial material 402 into a staircase with cascading tiers, the memory cell channels 450 may be independently selectable.

As illustrated in FIG. 4C, after the staircase formation is recessed as shown in FIG. 4A, the oxide material 401 may be formed (e.g., re-deposited) to fill in a remaining space. The oxide material 401 may thereby extend a first length 411 in a horizontal direction (e.g., the x-direction). For example, at each alternating layer of the oxide material 401, the oxide material 401 may extend a full first length 411. At each layer of the sacrificial material 402 (e.g., subsequently to be replaced with a metal material), the sacrificial material 402 may extend a respective second length. For example, the layer of the sacrificial material 402-a in FIG. 4C may extend a respective second length 412 in the horizontal direction, and a portion of the oxide material 401 extending in a remaining portion of the layer. That is, the portion of the oxide material 401 in the layer 402-a may be equal to a difference between the first length 410 and the second length 412. The respective second lengths 412 of each layer of the sacrificial material 402 may increase as the tiers in the stack decrease. For example, layers of the sacrificial material 402 that are closer to a substrate may have a longer respective second length 412 than layers of the sacrificial material 402 that are further from the substrate to form the cascading staircase formation.

FIG. 4D illustrates an example of a memory architecture 400-d in the xz plane. For example, the memory architecture 400-d shows another example of a cross-sectional view of the memory architecture 400-b. In some cases, the memory architecture 400-d shows an example of the memory architecture 400-b including tiers of the sacrificial material that, once formed into word lines, serve as dummy gates. For example, a tier 402-b and a tier 402-c may not be used as functional word lines when replaced with a metal material, and may instead serve to activate or turn on a portion of the memory architecture 400-d, such as a space 413.

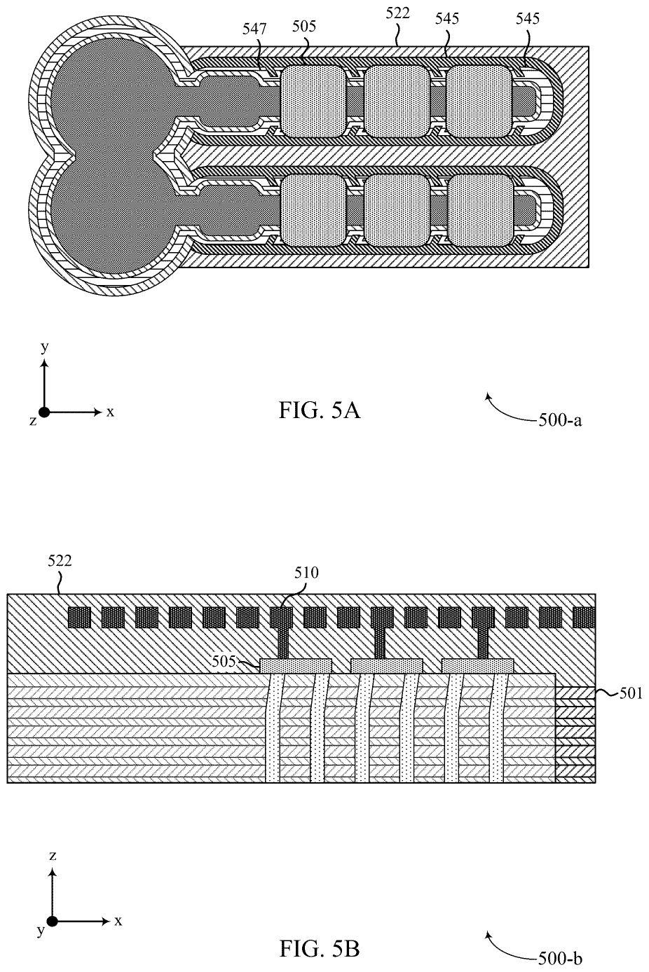

FIGS. 5A and 5B show examples of a memory architecture 500 that supports selector for vertical planar cell and in-pillar cell structures in accordance with examples as disclosed herein. The memory architecture 500 may be an example of the memory architectures described herein. For example, the memory architecture 500 may include memory cell channels formed in a stack of materials and separated by oxidized notches within memory slots, as described with reference to FIGS. 2A through 4C. The memory architecture 500 may include a separation material 522, an oxide material 545, and a storage material 547, which may be examples of corresponding aspects described herein.

FIG. 5A illustrates an example of a memory architecture 500-a in the xy plane. The memory architecture 500-a may include bit line contacts 505. In some cases, the bit line contacts 505 may couple with groups of memory cell channels (e.g., memory cell channels described herein). A bit line contact 505 may be activated by receiving a voltage, which may activate one of the memory cell channels coupled with the bit line contact 505. The memory cell channels may be independently selectable based on one or more implantation regions and a configuration of the stack of materials. For example, the memory cell channels may be independently selectable based on multiple implantation regions as described with reference to FIGS. 3A and 4B. Alternatively, the memory cell channels may be independently selectable based on a single implantation region and a staircase formation of word lines in the stack of materials.

FIG. 5B illustrates an example of a memory architecture 500-b in the xz plane. The memory architecture 500-b shows a cross-sectional view of the memory architecture 500-a in the xz plane. As shown in FIG. 5B, a bit line 510 may couple with a bit line contact 505. The bit line contact 505 may couple with multiple memory cell channels, which may be independently selectable as described herein. For example, a bit line 510 may receive a voltage and the voltage may be transferred to the bit line contact 505 and the memory cell channels. If the bit line contact 505 is coupled with four memory cell channels, only one memory cell channel may be activated from the received voltages based on one or more implantation regions, a staircase formation of the stack of materials, or both. The memory architecture 500-b may include a tiers of a metal material 501 (e.g., word lines).

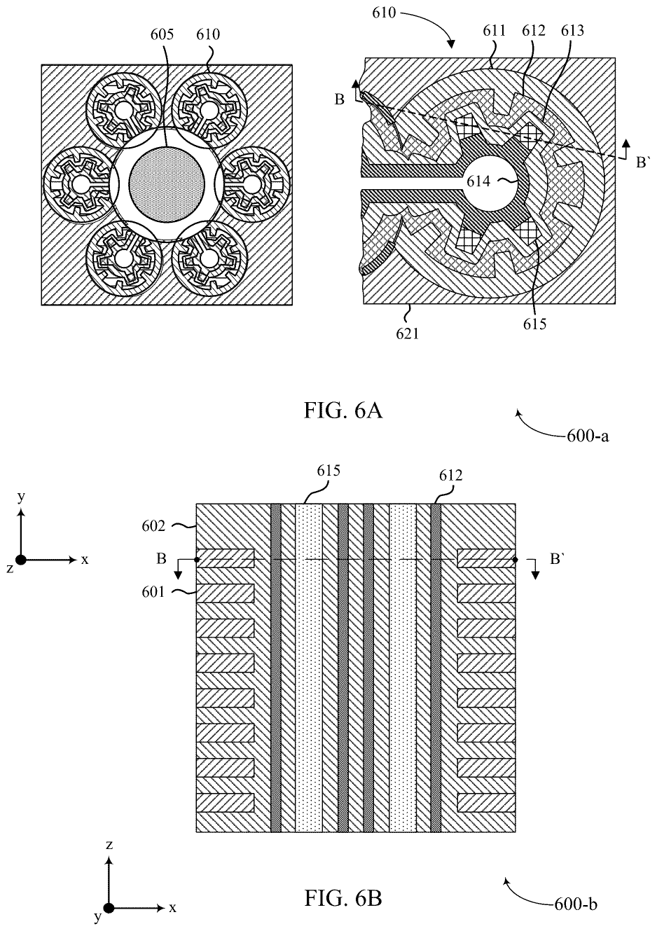

FIGS. 6A and 6B show examples of a memory architecture 600 that supports selector for vertical planar cell and in-pillar cell structures in accordance with examples as disclosed herein. The memory architecture 600 may support memory cell channels formed in a memory pillar using techniques similar to those described with respect to FIGS. 2A through 2M.

FIG. 6A illustrates an example of a memory architecture 600-a in the xy plane (e.g., a top down view). A central pillar 605 and one or more memory pillars 610 may be formed in a stack of materials, which may include one or more layers of a sacrificial material 601 and one or more layers of an oxide material 602 (e.g., alternating layers). A top layer of the stack surrounding the memory pillars may be the sacrificial material 601. The central pillar 605 may provide access to one or more surrounding memory pillars 610. The memory pillars 610 may be filled with an oxide material 611 (e.g., a blocking oxide lining a sidewall of the memory pillar 610), a storage material 612 (e.g., a storage nitride), and a separation material 613 (e.g., a tunnel nitride). Portions of the oxide material 611 may extend into the memory pillar 610 forming notches of the oxide material 611. Memory cell channels 615 may be formed in remaining spaces between notches after depositing the separation material 613. An oxide terminate 614 may line a remaining sidewall of the memory pillar 610. The memory cell channels 615 may include a metal material and may couple with one or more memory cells including the storage material 612 in the stack of materials.

FIG. 6B illustrates an example of a memory architecture 600-b in the xz plane. The memory architecture 600-b may be an example of the memory architecture 600-a at a cross-section of the B-B′ line in FIG. 6A. As shown in FIG. 6B, the memory cell channels 615 may extend from a top layer of the stack of materials to a bottom of the stack of materials. In some cases, the memory cell channels 615 may couple with memory cells at one or more tiers of sacrificial material 621 corresponding to word lines (once replaced with a metal material). For example, the memory cells may include the storage material 612, and may be located between a memory cell channel 615 tier of the sacrificial material 621.

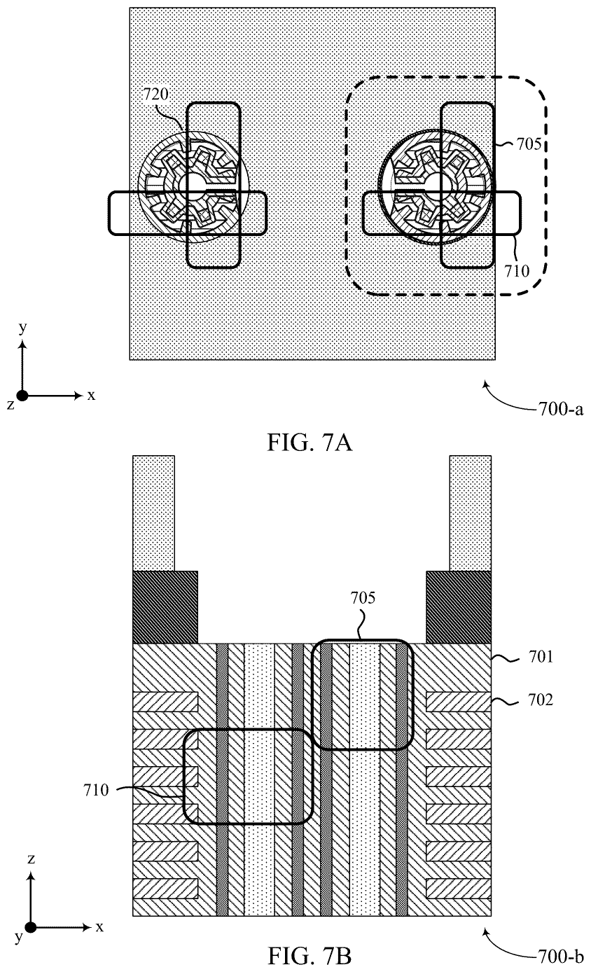

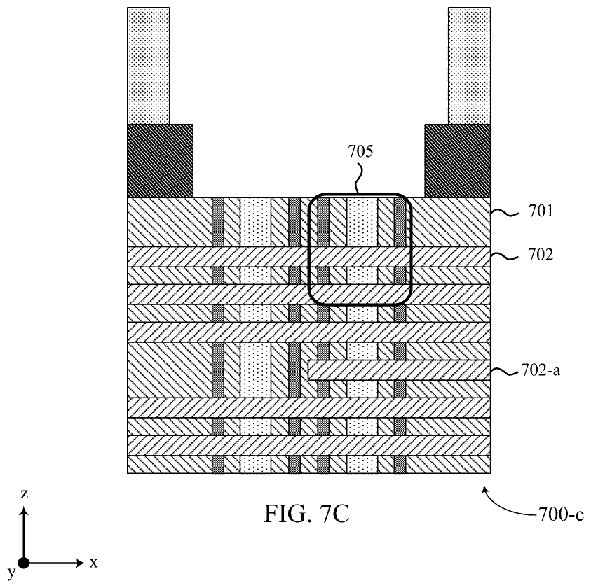

FIGS. 7A through 7C show examples of a memory architecture 700 that supports selector for vertical planar cell and in-pillar cell structures in accordance with examples as disclosed herein. The memory architecture 700 may implement an in-pillar memory cell channel structure as described with reference to FIGS. 6A and 6B. The memory architecture 700 may include a stack of materials including one or more layers of an oxide material 701 and one or more layers of a sacrificial material 702.

FIG. 7A illustrates an example of a memory architecture 700-a in the xy plane (e.g., a top down view). The memory architecture 700-a include memory pillars 720, which may be examples of memory pillars 610 described with reference to FIG. 6. The memory pillars may be implanted with a first material (e.g., phosphorus or boron) at one or more implantation regions, such as an implantation region 705 and an implantation region 710. The implantation regions may change the electrical properties of memory cell channels. the memory cell channels of a memory pillar 720 may be coupled with a common bit line contact and may be independently selectable based on the implantation regions, as described herein.

FIG. 7B illustrates an example of a memory architecture 700-b in the xz plane. For example, the memory architecture 700-b may be a cross-sectional view of the memory architecture 700-a. As shown in FIG. 7B, the implantation regions 705 and 710 may extend to different depths in the stack of materials and may originate from different points, which may support the memory cell channels being independently selectable when coupled with a common bit line contact. In some examples, the tiers of sacrificial material in the stack may be formed into a staircase formation with cascading tiers.

FIG. 7C illustrates an example of a memory architecture 700-c in the xz plane. For example, the memory architecture 700-c may be a cross-sectional view of the memory architecture 700-a. In some cases, the memory architecture 700-c illustrates an example where one or more tiers of the sacrificial material 702 may extend to different lengths (e.g., similar to the staircase formation described with reference to FIGS. 4A through 4C). For example, the memory architecture 700-c may include a tier of the sacrificial material 702-a that extends a length, in the x-direction, that is less than other tiers of the sacrificial material 702. In such examples, the memory architecture 700-c may include a single implantation region 705 (e.g., due to the staircase formation allowing for additional selection capability, as described herein). For example, the tier of sacrificial material 702-a, after being formed into a word line, may support independent selection between multiple memory cell channels based on the tier of sacrificial material 702-a not extending to a portion of the memory cell channels. Further, the implantation region 705 may support independent selection between memory cell channels contacting the tier of sacrificial material 702-a.

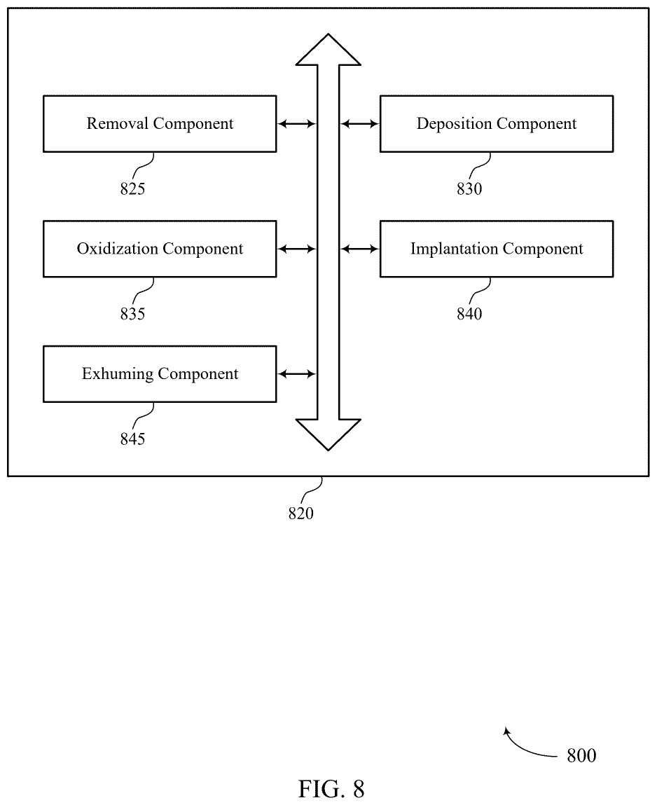

FIG. 8 shows a block diagram 800 of a manufacturing system 820 that supports selector for vertical planar cell and in-pillar cell structures in accordance with examples as disclosed herein. The manufacturing system 820 may be an example of aspects of a manufacturing system as described with reference to FIGS. 1 through 7. The manufacturing system 820, or various components thereof, may be an example of means for performing various aspects of selector for vertical planar cell and in-pillar cell structures as described herein. For example, the manufacturing system 820 may include a removal component 825, a deposition component 830, an oxidization component 835, an implantation component 840, an exhuming component 845, or any combination thereof. Each of these components, or components of subcomponents thereof (e.g., one or more processors, one or more memories), may communicate, directly or indirectly, with one another (e.g., via one or more buses).

The removal component 825 may be configured as or otherwise support a means for forming a first cavity and a second cavity that extend in a vertical direction from a top layer of a stack of materials to a substrate positioned beneath the stack of materials. The deposition component 830 may be configured as or otherwise support a means for forming a sacrificial material in the second cavity. In some examples, the removal component 825 may be configured as or otherwise support a means for expanding a size of the first cavity, where the first cavity contacts the sacrificial material in the second cavity based at least in part on expansion of the size of the first cavity. In some examples, the removal component 825 may be configured as or otherwise support a means for removing, via the first cavity based at least in part on expansion, the sacrificial material of the second cavity in a plurality of phases, where each phase of the plurality of phases removes a respective portion of the sacrificial material to form a respective recess in the sacrificial material. The oxidization component 835 may be configured as or otherwise support a means for oxidizing, during each phase of the plurality of phases, a portion of the sacrificial material to form an oxidized notch that marks an edge of a respective recess associated with a respective phase, where the plurality of phases re-form the second cavity including a plurality of recesses between each pair of a plurality of oxidized notches. In some examples, the deposition component 830 may be configured as or otherwise support a means for forming, after completing the plurality of phases and within each recess of the plurality of recesses based at least in part on the plurality of oxidized notches, a plurality of memory cell channels extending in the vertical direction and distributed in a horizontal direction along one or more axes within the second cavity.

In some examples, the implantation component 840 may be configured as or otherwise support a means for implanting a material in a first region of the stack that overlaps with at least a portion of a first memory cell channel of the plurality of memory cell channels, the material configured to change electrical properties of the first memory cell channel. In some examples, the implantation component 840 may be configured as or otherwise support a means for implanting the material in a second region of the stack that overlaps with at least a portion of a second memory cell channel of the plurality of memory cell channels, the material configured to change electrical properties of the second memory cell channel.

In some examples, to support removing the sacrificial material of the second cavity, the removal component 825 may be configured as or otherwise support a means for removing, in each first phase of a plurality of first phases, a respective first portion of a layer of oxide material in the stack of materials and a respective second portion of a layer of the sacrificial material in the stack of materials, where a length, in the horizontal direction, of remaining oxide material in the layer of the oxide material is different than a second length, in the horizontal direction, of remaining sacrificial material in the layer of the sacrificial material, and where the plurality of first phases remove a plurality of layers of the oxide material and a plurality of layers of the sacrificial material to form a staircase formation of cascading tiers of materials in the stack, and where a shape of the second cavity is based at least in part on the staircase formation.

In some examples, the deposition component 830 may be configured as or otherwise support a means for forming, after forming the sacrificial material in the second cavity and based at least in part on a pattern, a plurality of strips of a first material that extend across the second cavity and are dispersed in the horizontal direction, where removing, in each phase, the sacrificial material to form a respective recess may include the removal component 825 being configured as or otherwise supporting a means for removing the sacrificial material to a respective strip of the plurality of strips of the first material. In some examples, the exhuming component 845 may be configured as or otherwise support a means for removing the respective strip of the first material after the respective phase.

In some examples, the deposition component 830 may be configured as or otherwise support a means for forming, after completing the plurality of phases and within the second cavity, a storage material that lines each recess of the plurality of recesses and at least partially surrounds each notch of the plurality of oxidized notches, where forming the plurality of memory cell channels is based at least in part on forming a conductive material within each recess after forming the storage material.

In some examples, the described functionality of the manufacturing system 820, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the manufacturing system 820, or various components thereof, may be implemented at least in part by instructions (e.g., stored in memory, non-transitory computer-readable medium) executable by such at least one processor.

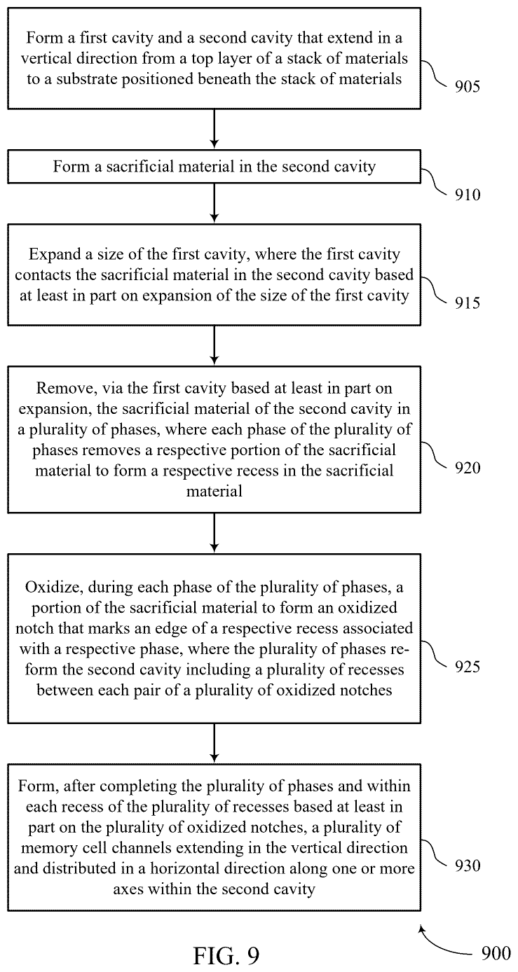

FIG. 9 shows a flowchart illustrating a method 900 that supports selector for vertical planar cell and in-pillar cell structures in accordance with examples as disclosed herein. The operations of method 900 may be implemented by a manufacturing system or its components as described herein. For example, the operations of method 900 may be performed by a manufacturing system as described with reference to FIGS. 1 through 8. In some examples, a manufacturing system may execute a set of instructions to control the functional elements of the device to perform the described functions. Additionally, or alternatively, the manufacturing system may perform aspects of the described functions using special-purpose hardware.

At 905, the method may include forming a first cavity and a second cavity that extend in a vertical direction from a top layer of a stack of materials to a substrate positioned beneath the stack of materials. In some examples, aspects of the operations of 905 may be performed by a removal component 825 as described with reference to FIG. 8.

At 910, the method may include forming a sacrificial material in the second cavity. In some examples, aspects of the operations of 910 may be performed by a deposition component 830 as described with reference to FIG. 8.

At 915, the method may include expanding a size of the first cavity, where the first cavity contacts the sacrificial material in the second cavity based at least in part on expansion of the size of the first cavity. In some examples, aspects of the operations of 915 may be performed by an removal component 825 as described with reference to FIG. 8.

At 920, the method may include removing, via the first cavity based at least in part on expansion, the sacrificial material of the second cavity in a plurality of phases, where each phase of the plurality of phases removes a respective portion of the sacrificial material to form a respective recess in the sacrificial material. In some examples, aspects of the operations of 920 may be performed by a removal component 825 as described with reference to FIG. 8.

At 925, the method may include oxidizing, during each phase of the plurality of phases, a portion of the sacrificial material to form an oxidized notch that marks an edge of a respective recess associated with a respective phase, where the plurality of phases re-form the second cavity including a plurality of recesses between each pair of a plurality of oxidized notches. In some examples, aspects of the operations of 925 may be performed by an oxidization component 835 as described with reference to FIG. 8.

At 930, the method may include forming, after completing the plurality of phases and within each recess of the plurality of recesses based at least in part on the plurality of oxidized notches, a plurality of memory cell channels extending in the vertical direction and distributed in a horizontal direction along one or more axes within the second cavity. In some examples, aspects of the operations of 930 may be performed by a deposition component 830 as described with reference to FIG. 8.

In some examples, an apparatus as described herein may perform a method or methods, such as the method 900. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a first cavity and a second cavity that extend in a vertical direction from a top layer of a stack of materials to a substrate positioned beneath the stack of materials; forming a sacrificial material in the second cavity; expanding a size of the first cavity, where the first cavity contacts the sacrificial material in the second cavity based at least in part on expansion of the size of the first cavity; removing, via the first cavity based at least in part on expansion, the sacrificial material from the second cavity in a plurality of phases, where each phase of the plurality of phases removes a respective portion of the sacrificial material to form a respective recess in the sacrificial material; oxidizing, during each phase of the plurality of phases, a portion of the sacrificial material to form an oxidized notch that marks an edge of a respective recess associated with a respective phase, where the plurality of phases re-form the second cavity including a plurality of recesses between each pair of a plurality of oxidized notches; and forming, after completing the plurality of phases and within each recess of the plurality of recesses based at least in part on the plurality of oxidized notches, a plurality of memory cell channels extending in the vertical direction and distributed in a horizontal direction along one or more axes within the second cavity.

Aspect 2: The method, apparatus, or non-transitory computer-readable medium of aspect 1, further including operations, features, circuitry, logic, means, or instructions, or any combination thereof for implanting a material in a first region of the stack that overlaps with at least a portion of a first memory cell channel of the plurality of memory cell channels, the material configured to change electrical properties of the first memory cell channel and implanting the material in a second region of the stack that overlaps with at least a portion of a second memory cell channel of the plurality of memory cell channels, the material configured to change electrical properties of the second memory cell channel.

Aspect 3: The method, apparatus, or non-transitory computer-readable medium of any of aspects 1 through 2, where removing the sacrificial material from the second cavity includes operations, features, circuitry, logic, means, or instructions, or any combination thereof for removing, in each first phase of a plurality of first phases, a respective first portion of a layer of oxide material in the stack of materials and a respective second portion of a layer of the sacrificial material in the stack of materials, where a length, in the horizontal direction, of remaining oxide material in the layer of the oxide material is different than a second length, in the horizontal direction, of remaining sacrificial material in the layer of the sacrificial material, and where the plurality of first phases remove a plurality of layers of the oxide material and a plurality of layers of the sacrificial material to form a staircase formation of cascading tiers of materials in the stack, and where a shape of the second cavity is based at least in part on the staircase formation.

Aspect 4: The method, apparatus, or non-transitory computer-readable medium of any of aspects 1 through 3, further including operations, features, circuitry, logic, means, or instructions, or any combination thereof for forming, after forming the sacrificial material in the second cavity and based at least in part on a pattern, a plurality of strips of a first material that extend across the second cavity and are dispersed in the horizontal direction, where removing, in each phase, the sacrificial material to form a respective recess includes; removing the sacrificial material to a respective strip of the plurality of strips of the first material; and removing the respective strip of the first material after the respective phase.

Aspect 5: The method, apparatus, or non-transitory computer-readable medium of any of aspects 1 through 4, further including operations, features, circuitry, logic, means, or instructions, or any combination thereof for forming, after completing the plurality of phases and within the second cavity, a storage material that lines each recess of the plurality of recesses and at least partially surrounds each notch of the plurality of oxidized notches, where forming the plurality of memory cell channels is based at least in part on forming a conductive material within each recess after forming the storage material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 6: An apparatus, including: a substrate; a stack including a plurality of layers of an oxide material and a plurality of layers of a metal material stacked above the substrate in a vertical direction, where the plurality of layers of the metal material form a staircase formation of cascading tiers of the metal material; a plurality of first memory cell channels extending through the stack in the vertical direction and distributed along a first axis in a horizontal direction, each first memory cell channel of the plurality of first memory cell channels coupled with a memory cell storage material within a respective layer of the plurality of layers of the metal material; a plurality of second memory cell channels extending through the stack in the vertical direction and distributed along a second axis in the horizontal direction, each second memory cell channel of the plurality of second memory cell channels coupled with the memory cell storage material within the respective layer of the plurality of layers of the metal material; and an implantation region implanted with a first material configured to change electrical properties associated with the plurality of first memory cell channels, where the implantation region implanted with the first material includes the plurality of first memory cell channels and is separate from the plurality of second memory cell channels.

Aspect 7: The apparatus of aspect 6, where: the plurality of layers of the oxide material include oxide material extending at least a first length in the horizontal direction; and the staircase formation of the cascading tiers of the metal material is based at least in part on each layer of the plurality of layers of the metal material including the metal material extending a respective length in the horizontal direction and at least a portion of the oxide material in a remaining portion of the layer.

Aspect 8: The apparatus of aspect 7, where the respective length of metal material in each of the plurality of layers of the metal material is less than or equal to the first length of the oxide material in each of the plurality of layers of the oxide material.

Aspect 9: The apparatus of any of aspects 6 through 8, further including: a contact coupled with a bit line and with at least one first memory cell channel of the plurality of first memory cell channels and at least one second memory cell channel of the plurality of second memory cell channels, where the at least one first memory cell channel and the at least one second memory cell channel are coupled with the memory cell storage material within a first layer of the plurality of layers of the metal material, and where the at least one first memory cell channel is independently selectable from the at least one second memory cell channel based at least in part on the implantation region including the at least one first memory cell channel.

Aspect 10: The apparatus of any of aspects 6 through 9, further including: a contact coupled with a bit line and with at least two first memory cell channels of the plurality of first memory cell channels, where the bit line is configured to activate the at least two first memory cell channels; and a memory cell including the memory cell storage material within a first layer of the plurality of layers of the metal material, the memory cell coupled with a target memory cell channel of the at least two first memory cell channels based at least in part on the staircase formation, where the memory cell is independently selectable from other memory cells coupled with other first memory cell channels of the at least two first memory cell channels based at least in part on the bit line and the first layer of the metal material.

Aspect 11: The apparatus of any of aspects 6 through 10, where: the implantation region overlaps with at least a portion of each first memory cell channel of the plurality of first memory cell channels in the vertical direction; and a length of the implantation region is greater than or equal to a length of the staircase formation of the cascading tiers of the metal material in the horizontal direction.

Aspect 12: The apparatus of any of aspects 6 through 11, where the electrical properties associated with the plurality of first memory cell channels include at least a threshold access voltage associated with each first memory cell channel of the plurality of first memory cell channels.

Aspect 13: The apparatus of any of aspects 6 through 12, where the first material includes phosphorus, boron, or both.

An apparatus is described. The following provides an overview of aspects of the apparatus as described herein:

Aspect 14: An apparatus, including: a substrate; a stack including a plurality of layers of an oxide material and a plurality of layers of a metal material stacked above the substrate in a vertical direction; a plurality of memory cell channels each extending through the stack in the vertical direction; a contact coupled with the plurality of memory cell channels; a first implantation region implanted with a material configured to change electrical properties of one or more memory cell channels, where the first implantation region at least partially overlaps with a first memory cell channel from the plurality of memory cell channels coupled with the contact; and a second implantation region implanted with the material configured to change the electrical properties of the one or more memory cell channels, where the second implantation region at least partially overlaps with a second memory cell channel from the plurality of memory cell channels coupled with the contact, and where the first memory cell channel is independently selectable from the second memory cell channel based at least in part on the first implantation region and the second implantation region.

Aspect 15: The apparatus of aspect 14, where: the first implantation region is implanted with the material extending a first distance into the stack in the vertical direction and the second implantation region is implanted with the material extending a second distance into the stack in the vertical direction, the second distance different from the first distance; and first electrical properties of the first memory cell channel are different from second electrical properties of the second memory cell channel based at least in part on the first distance being different from the second distance, the first electrical properties including a first threshold voltage associated with the first memory cell channel and the second electrical properties including a second threshold voltage associated with the second memory cell channel.

Aspect 16: The apparatus of any of aspects 14 through 15, where the second implantation region at least partially overlaps with the first memory cell channel and the second memory cell channel, and first electrical properties of the first memory cell channel are different from second electrical properties of the second memory cell channel based at least in part on both the first implantation region and the second implantation region overlapping with the first memory cell channel.

Aspect 17: The apparatus of any of aspects 14 through 16, further including: a third implantation region implanted with the material configured to change the electrical properties of the one or more memory cell channels, where the third implantation region at least partially overlaps with a third memory cell channel from the plurality of memory cell channels coupled with the contact, and where the third memory cell channel is independently selectable from the first memory cell channel and the second memory cell channel based at least in part on the third implantation region, the first implantation region, and the second implantation region.

Aspect 18: The apparatus of any of aspects 14 through 17, where the plurality of memory cell channels coupled with the contact includes a fourth memory cell channel that is independently selectable from the first memory cell channel and the second memory cell channel based at least in part on the fourth memory cell channel being separate from the first implantation region and the second implantation region.

Aspect 19: The apparatus of any of aspects 14 through 18, further including: a plurality of bit lines including at least a first bit line coupled with the contact and a second bit line coupled with a second contact, where the first bit line is configured to apply a voltage to the plurality of memory cell channels via the contact, and where a first effect of the voltage on the first memory cell channel is different from a second effect of the voltage on the second memory cell channel based at least in part on the first implantation region and the second implantation region.

Aspect 20: The apparatus of any of aspects 14 through 19, where the material includes phosphorus, boron, or both.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a substrate;
a stack comprising a plurality of layers of an oxide material and a plurality of layers of a metal material stacked above the substrate in a vertical direction, wherein the plurality of layers of the metal material form a staircase formation of cascading tiers of the metal material;
a plurality of first memory cell channels extending through the stack in the vertical direction and distributed along a first axis in a horizontal direction, each first memory cell channel of the plurality of first memory cell channels coupled with a memory cell storage material within a respective layer of the plurality of layers of the metal material;
a plurality of second memory cell channels extending through the stack in the vertical direction and distributed along a second axis in the horizontal direction, each second memory cell channel of the plurality of second memory cell channels coupled with the memory cell storage material within the respective layer of the plurality of layers of the metal material; and
an implantation region implanted with a first material configured to change electrical properties associated with the plurality of first memory cell channels, wherein the implantation region implanted with the first material comprises the plurality of first memory cell channels and is separate from the plurality of second memory cell channels.

2. The apparatus of claim 1, wherein:
the plurality of layers of the oxide material comprise oxide material extending at least a first length in the horizontal direction; and
the staircase formation of the cascading tiers of the metal material is based at least in part on each layer of the plurality of layers of the metal material comprising the metal material extending a respective length in the horizontal direction and at least a portion of the oxide material in a remaining portion of the layer.

3. The apparatus of claim 2, wherein the respective length of metal material in each of the plurality of layers of the metal material is less than or equal to the first length of the oxide material in each of the plurality of layers of the oxide material.

4. The apparatus of claim 1, further comprising:
a contact coupled with a bit line and with at least one first memory cell channel of the plurality of first memory cell channels and at least one second memory cell channel of the plurality of second memory cell channels, wherein the at least one first memory cell channel and the at least one second memory cell channel are coupled with the memory cell storage material within a first layer of the plurality of layers of the metal material, and wherein the at least one first memory cell channel is independently selectable from the at least one second memory cell channel based at least in part on the implantation region comprising the at least one first memory cell channel.

5. The apparatus of claim 1, further comprising:
a contact coupled with a bit line and with at least two first memory cell channels of the plurality of first memory cell channels, wherein the bit line is configured to activate the at least two first memory cell channels; and
a memory cell comprising the memory cell storage material within a first layer of the plurality of layers of the metal material, the memory cell coupled with a target memory cell channel of the at least two first memory cell channels based at least in part on the staircase formation, wherein the memory cell is independently selectable from other memory cells coupled with other first memory cell channels of the at least two first memory cell channels based at least in part on the bit line and the first layer of the metal material.

6. The apparatus of claim 1, wherein:
the implantation region overlaps with at least a portion of each first memory cell channel of the plurality of first memory cell channels in the vertical direction; and
a length of the implantation region is greater than or equal to a length of the staircase formation of the cascading tiers of the metal material in the horizontal direction.

7. The apparatus of claim 1, wherein the electrical properties associated with the plurality of first memory cell channels comprise at least a threshold access voltage associated with each first memory cell channel of the plurality of first memory cell channels.

8. The apparatus of claim 1, wherein the first material comprises phosphorus, boron, or both.

9. An apparatus, comprising:
a substrate;
a stack comprising a plurality of layers of an oxide material and a plurality of layers of a metal material stacked above the substrate in a vertical direction;
a plurality of memory cell channels each extending through the stack in the vertical direction;
a contact coupled with the plurality of memory cell channels;
a first implantation region implanted with a material configured to change electrical properties of one or more memory cell channels, wherein the first implantation region at least partially overlaps with a first memory cell channel from the plurality of memory cell channels coupled with the contact; and
a second implantation region implanted with the material configured to change the electrical properties of the one or more memory cell channels, wherein the second implantation region at least partially overlaps with a second memory cell channel from the plurality of memory cell channels coupled with the contact, and wherein the first memory cell channel is independently selectable from the second memory cell channel based at least in part on the first implantation region and the second implantation region.

10. The apparatus of claim 9, wherein:
the first implantation region is implanted with the material extending a first distance into the stack in the vertical direction and the second implantation region is implanted with the material extending a second distance into the stack in the vertical direction, the second distance different from the first distance; and
first electrical properties of the first memory cell channel are different from second electrical properties of the second memory cell channel based at least in part on the first distance being different from the second distance, the first electrical properties comprising a first threshold voltage associated with the first memory cell channel and the second electrical properties comprising a second threshold voltage associated with the second memory cell channel.

11. The apparatus of claim 9, wherein:
the second implantation region at least partially overlaps with the first memory cell channel and the second memory cell channel, and
first electrical properties of the first memory cell channel are different from second electrical properties of the second memory cell channel based at least in part on both the first implantation region and the second implantation region overlapping with the first memory cell channel.

12. The apparatus of claim 9, further comprising:
a third implantation region implanted with the material configured to change the electrical properties of the one or more memory cell channels, wherein the third implantation region at least partially overlaps with a third memory cell channel from the plurality of memory cell channels coupled with the contact, and wherein the third memory cell channel is independently selectable from the first memory cell channel and the second memory cell channel based at least in part on the third implantation region, the first implantation region, and the second implantation region.

13. The apparatus of claim 9, wherein the plurality of memory cell channels coupled with the contact comprises a fourth memory cell channel that is independently selectable from the first memory cell channel and the second memory cell channel based at least in part on the fourth memory cell channel being separate from the first implantation region and the second implantation region.

14. The apparatus of claim 9, further comprising:
a plurality of bit lines comprising at least a first bit line coupled with the contact and a second bit line coupled with a second contact, wherein the first bit line is configured to apply a voltage to the plurality of memory cell channels via the contact, and wherein a first effect of the voltage on the first memory cell channel is different from a second effect of the voltage on the second memory cell channel based at least in part on the first implantation region and the second implantation region.

15. The apparatus of claim 9, wherein the material comprises phosphorus, boron, or both.

16. A method, comprising:
forming a first cavity and a second cavity that extend in a vertical direction from a top layer of a stack of materials to a substrate positioned beneath the stack of materials;
forming a sacrificial material in the second cavity;
expanding a size of the first cavity, wherein the first cavity contacts the sacrificial material in the second cavity based at least in part on expansion of the size of the first cavity;
removing, via the first cavity based at least in part on expansion, the sacrificial material from the second cavity in a plurality of phases, wherein each phase of the plurality of phases removes a respective portion of the sacrificial material to form a respective recess in the sacrificial material;
oxidizing, during each phase of the plurality of phases, a portion of the sacrificial material to form an oxidized notch that marks an edge of a respective recess associated with a respective phase, wherein the plurality of phases re-form the second cavity including a plurality of recesses between each pair of a plurality of oxidized notches; and
forming, after completing the plurality of phases and within each recess of the plurality of recesses based at least in part on the plurality of oxidized notches, a plurality of memory cell channels extending in the vertical direction and distributed in a horizontal direction along one or more axes within the second cavity.

17. The method of claim 16, further comprising:
implanting a material in a first region of the stack that overlaps with at least a portion of a first memory cell channel of the plurality of memory cell channels, the material configured to change electrical properties of the first memory cell channel; and
implanting the material in a second region of the stack that overlaps with at least a portion of a second memory cell channel of the plurality of memory cell channels, the material configured to change electrical properties of the second memory cell channel.

18. The method of claim 16, wherein removing the sacrificial material from the second cavity comprises:
removing, in each first phase of a plurality of first phases, a respective first portion of a layer of oxide material in the stack of materials and a respective second portion of a layer of the sacrificial material in the stack of materials, wherein a length, in the horizontal direction, of remaining oxide material in the layer of the oxide material is different than a second length, in the horizontal direction, of remaining sacrificial material in the layer of the sacrificial material, and wherein the plurality of first phases remove a plurality of layers of the oxide material and a plurality of layers of the sacrificial material to form a staircase formation of cascading tiers of materials in the stack, and wherein a shape of the second cavity is based at least in part on the staircase formation.

19. The method of claim 16, further comprising:
forming, after forming the sacrificial material in the second cavity and based at least in part on a pattern, a plurality of strips of a first material that extend across the second cavity and are dispersed in the horizontal direction, wherein removing, in each phase, the sacrificial material to form a respective recess comprises:
removing the sacrificial material to a respective strip of the plurality of strips of the first material; and
removing the respective strip of the first material after the respective phase.

20. The method of claim 16, further comprising:
forming, after completing the plurality of phases and within the second cavity, a storage material that lines each recess of the plurality of recesses and at least partially surrounds each notch of the plurality of oxidized notches, wherein forming the plurality of memory cell channels is based at least in part on forming a conductive material within each recess after forming the storage material.
